(19) United States
(12) Patent Application Publication
(10) Pub. No.: US 2025/0271501 A1
(43) Pub. Date: Aug. 28, 2025

(54) CIRCUIT INPUT/OUTPUT (I/O) TEST SYSTEM

(71) Applicant: TEXAS INSTRUMENTS INCORPORATED, DALLAS, TX (US)

(72) Inventors: Mudasir KAWOOSA, BANGALORE (IN); Pervez GARG, BANGALORE (IN); Pranjal GIRI, HOWRAH (IN)

(21) Appl. No.: 18/587,317

(22) Filed: Feb. 26, 2024

(51) Int. Cl. G01R 31/3185; G01R 31/3181

(52) U.S. Cl. CPC G01R 31/318536; G01R 31/31813; G01R 31/318541; G01R 31/318552; G01R 31/318572

(57) ABSTRACT

One example includes a circuit. The circuit includes a circuit core configured to perform an operational function and scan-chain registers configured to propagate a set of system-on-chip (SoC) scan data that is input to the circuit generated from an automatic test pattern generator (ATPG) to set a different device state of the circuit core at each shift of the SoC scan data. The circuit further includes a plurality of bidirectional input/output (I/O) circuits each comprising a bidirectional I/O control and testing logic, the testing logic being configured to alternately facilitate input parametric testing and output parametric testing of an I/O pad of the respective bidirectional I/O control at each shift of the set of SoC scan data via a pin parametric measurement unit (PPMU).

### TECHNICAL FIELD

This description relates to electronic circuits, and more specifically to a circuit input/output (I/O) test system.

### BACKGROUND

Integrated circuits (ICs) are typically fabricated in bulk on a semiconductor wafer. Fabricated ICs undergo a variety of different operational tests using automated test equipment (ATE). For example, the ATE can include contacts that implement parametric tests on the inputs and outputs (I/O) of the ICs, as well as other types of tests that implement other contacts of the ICs, such as quiescent current measurement test using a digital power supply (DPS). As an example, the parametric tests can be provided based on established standards, such as IEEE 1149.1. Such tests can be performed at either the wafer probe level on the semiconductor wafer, or at a final test level on the I/O pins of the package of a given IC chip. While testing is essential to ensure operational effectiveness of the ICs, testing can be time-consuming based on loading and unloading test data (e.g., via a scan-chain) and corresponding measurements (current/voltage).

### SUMMARY

One example includes a circuit. The circuit includes a circuit core configured to perform an operational function and scan-chain registers configured to propagate a set of system-on-chip (SoC) scan data that is input to the circuit generated from an automatic test pattern generator (ATPG) to set a different device state of the circuit core at each shift of the SoC scan data. The circuit further includes a plurality of bidirectional input/output (I/O) circuits each comprising a bidirectional I/O control, an I/O pad, and testing logic, the testing logic being configured to alternately facilitate input parametric testing and output parametric testing of the I/O pad via the respective bidirectional I/O control at each shift of the set of SoC scan data.

Another example includes a method for testing a circuit. The method includes providing a set of SoC scan data to a scan input terminal of the circuit from an ATPG. The method also includes shifting the set of SoC scan data through scan-chain registers in response to a scan enable signal and a scan clock signal that are each associated with propagating the SoC scan data through the circuit to provide a predetermined initial device state of a circuit core of the circuit. The method also includes alternately switching a bidirectional I/O control of each of a plurality of bidirectional I/O circuits between an input mode and an output mode at each shift of the set of SoC scan data via the scan enable signal and the scan clock signal subsequent to the predetermined initial device state. The method also includes providing input parametric testing of an I/O pad of each of the respective bidirectional I/O circuits in the input mode via a pin parametric measurement unit (PPMU) of ATE. The method further includes providing output parametric testing of the I/O pad of each of the respective bidirectional I/O circuits in the output mode via the PPMU of ATE.

Another example includes a circuit. The circuit includes a power terminal configured to receive input power to the circuit and a circuit core configured to perform an operational function. The circuit also includes scan-chain registers configured to propagate a set of SoC scan data that is input to the circuit from an ATPG to set a different device state of the circuit core at each shift of the SoC scan data. The system further includes a plurality of bidirectional I/O circuits each comprising a bidirectional I/O control, an I/O pad, and testing logic. The testing logic can be configured to facilitate input and output parametric testing of the I/O pad via the respective bidirectional I/O control by a PPMU concurrently with quiescent current measurement test of the circuit supply driven by a digital power supply (DPS) at each shift or end of shift of the set of SoC scan data.

Another example includes a method for testing a circuit. The method includes coupling a DPS to a power terminal of the circuit and providing a set of SoC scan data to a scan input terminal of the circuit generated using ATPG tool. The method also includes shifting the set of SoC scan data through scan-chain registers in response to a scan enable signal and a scan clock signal that are each associated with propagating the SoC scan data through the circuit to provide a predetermined initial device state of a circuit core of the circuit. The method also includes providing a parametric test of an I/O pad of each of a plurality of bidirectional I/O circuits via a PPMU at each shift or end of shift of the set of SoC scan data via the scan enable signal and the scan clock signal subsequent to the predetermined initial device state. The method further includes provision of quiescent current measurement test of the circuit supply driven by via the DPS concurrently with the parametric test of the respective I/O pad of each of the bidirectional I/O circuits at each shift or end of shift of the set of SoC scan data.

### BRIEF DESCRIPTION OF THE DRAWINGS

FIG. 1 is an example block diagram of a circuit test system.

FIG. 2 is an example block diagram of a device-under-test (DUT).

FIG. 3 is an example of a bidirectional input/output (I/O) test system.

FIG. 4 is an example diagram of a bidirectional control switching network.

FIG. 5 is an example diagram of a sense and drive-back network.

FIG. 6 is an example diagram of a testing process.

FIG. 7 is an example of a method for testing a circuit.

FIG. 8 is another example of a method for testing a circuit.

### DETAILED DESCRIPTION

This description relates to electronic circuits, and more specifically to a circuit input/output (I/O) test system. The circuit I/O test system can refer to a portion of an integrated circuit (IC) that can facilitate testing of the circuit via automated test equipment (ATE). As described herein, the circuit I/O test system can include a bidirectional switching control network and testing logic for each of a plurality of bidirectional I/O circuits, as well as a set of multiplexers for each of the bidirectional I/O circuits to facilitate switching between a normal operating mode and a test mode.

A circuit described herein can include a circuit core that is fabricated to perform an operational function (e.g., processing or an application specific function for which the IC was fabricated to perform). The circuit can also include the plurality of bidirectional I/O circuits that each include the test logic, the set of multiplexers, a bidirectional I/O control, and an I/O pad that can be coupled to a respective I/O pin of the package of the respective circuit. The testing described herein can be performed at post fabrication of the circuit, such as after singulation of the ICs from the wafer and/or after packaging of the ICs, thereby testing in a lower multi-site test environment to facilitate concurrent testing of a greater number of I/O circuits.

As an example, the testing described herein can conform to the IEEE 1149.1 standard of Joint Test Action Group (JTAG) testing that implements JTAG ports of a given circuit. Therefore, the ATE can implement test patterns generated from an automatic test pattern generator (ATPG) to load a set of system-on-chip (SoC) scan data in a scan-chain into the circuit. While the examples described herein are provided in the context of JTAG testing, other testing protocols and formats can be implemented that implement a scan-chain for testing. As described herein, based on operation of the circuit I/O test system in the circuit, the ATE can implement input and output parametric testing of the circuit, and quiescent current measurement test concurrently with the parametric testing on the single set of SoC scan data. Accordingly, the testing time for testing a set of circuits via the ATE can be significantly reduced, thereby allowing for significantly greater efficiency in testing a set of circuits.

For example, to provide the concurrent input and output parametric testing of a circuit, the testing logic of each of the bidirectional I/O circuits can be configured to alternately facilitate input parametric testing and output parametric testing of the respective I/O pad via the respective bidirectional I/O control at each shift of the set of SoC scan data. The input and output parametric testing can be provided via a pin parametric measurement unit (PPMU). For example, each of the circuits can include a bidirectional switching control network that is configured to alternately switch the bidirectional I/O control of each of the bidirectional I/O circuits to the input mode and the output mode, such that the testing logic can be configured to facilitate an input parametric test (e.g., either an input high parametric test or an input low parametric test) in the input mode and to facilitate an output parametric test (e.g., either an output high parametric test or an output low parametric test) in the output mode at alternating shifts of the set of SoC scan data. Additionally, the input and output parametric testing can be performed at each shift of the set of SoC scan data concurrently with quiescent current measurement test of the circuit supply that is provided at a power terminal via a digital power supply (DPS). Therefore, at each shift of the set of SoC scan data, the ATE can measure the quiescent current in each different device state corresponding to the respective separate shifts of the SoC scan data.

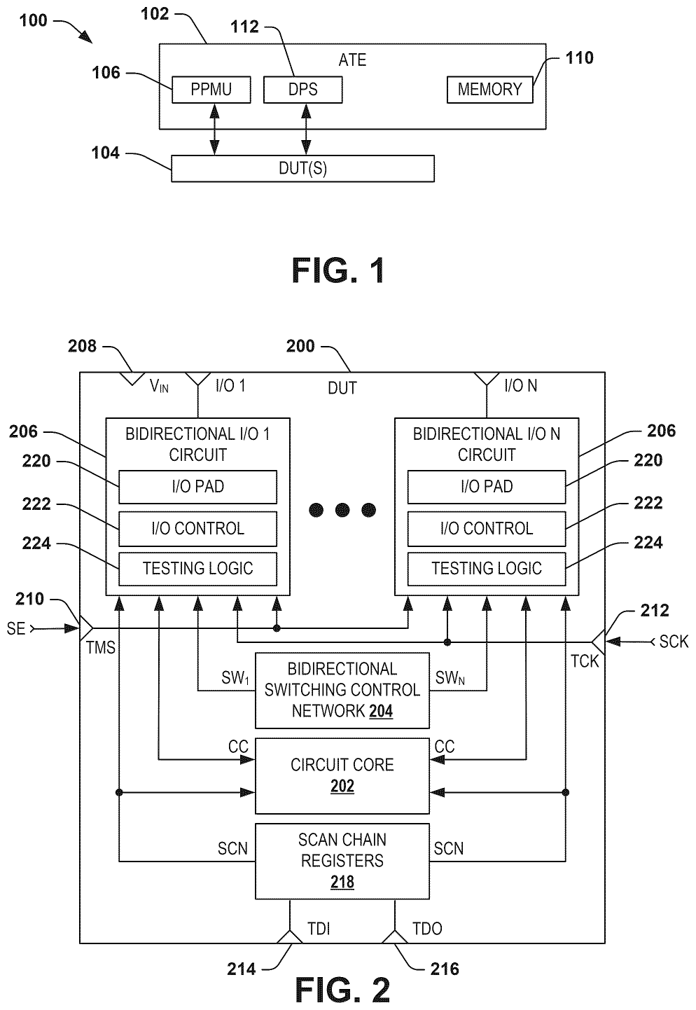

FIG. 1 is an example block diagram of a circuit test system 100. The circuit test system 100 includes an automated test equipment (ATE) 102 that is configured to test one or more fabricated circuits, demonstrated in the example of FIG. 1 as a devices-under-test (DUT(s)) 104. The ATE 102 can be configured to provide circuit testing at wafer level or in the final test (FT) stage of the packaged device, which can correspond to testing of the DUTs 104 after singulation and packaging of the DUTs 104 fabricated from a wafer. Therefore, a greater quantity of DUTs 104 can be concurrently tested by the ATE 102 by implementing the multisite contacts of the circuit packages of the DUTs 104. As described herein, the DUTs 104 can correspond to any of a variety of integrated circuits (ICs), such as processors, application specific integrated circuits (ASICs), or any other fabricated circuit.

The ATE 102 includes a pin parametric measurement unit (PPMU) 106 that is configured to implement input and output parametric tests of the DUTs 104. As described herein, the input parametric tests can include input high and input low tests, where logic-high and logic-low input signals, respectively, are provided to input/output (I/O) pads of each of a plurality of bidirectional I/O circuits of each of the DUTs in an input mode of the respective bidirectional I/O circuits. Similarly, the output parametric tests can include output high and output low tests, where logic-high and logic-low output signals, respectively, are provided from the I/O pads of each of the bidirectional I/O circuits of each of the DUTs in an output mode of the respective bidirectional I/O circuits. The parametric tests can be implemented based on providing a set of system-on-chip (SoC) scan data that is generated, for example, by an automatic test pattern generator (ATPG). The ATPG 108 can thus generate a set of SoC scan data that is provided to each of the DUTs 104. In the example of FIG. 1, the ATE 102 also includes a memory 110 that is configured to store data associated with the parametric tests, such as the set of SoC scan data generated by the ATPG 108 and the results of the parametric tests.

As described herein, to provide for a significantly more efficient testing operation of the DUTs 104, the ATE 102 can implement concurrent input and output parametric testing of each of the DUTs 104. For example, each of the DUTs 104 can include a bidirectional switching control network, and each of the bidirectional I/O circuits of each of the DUTs 104 can include an I/O pad, a bidirectional I/O control, and testing logic. The testing logic of each of the bidirectional I/O circuits can be configured to alternately facilitate input parametric testing and output parametric testing via the PPMU 106 of the respective I/O pad at each shift of the set of SoC scan data generated from the ATPG 108 tool. For example, the bidirectional switching control network of each of the DUTs 104 is configured to alternately switch the bidirectional I/O control of each of the bidirectional I/O circuits to the input mode and the output mode. The testing logic can thus be configured to facilitate an input parametric test (e.g., either an input high parametric test or an input low parametric test) in the input mode, and to facilitate an output parametric test (e.g., either an output high parametric test or an output low parametric test) in the output mode at alternating shifts of the set of SoC scan data.

In addition, as also described herein, to further provide for significantly more efficient testing operation of the DUTs 104, the ATE 102 can implement a quiescent current measurement test concurrently with the parametric testing on the single set of SoC scan data. In the example of FIG. 1, the ATE 102 also includes a digital power supply (DPS) 112 that is configured to provide power to each of the DUTs 104 via a respective power terminal associated with each of the DUTs 104. For example, at each shift of the set of SoC scan data, the ATE can measure the quiescent current in each different device state corresponding to the respective separate shifts of the SoC scan data. The quiescent current test can thus be performed concurrently with each input and output parametric test performed by the PPMU 106. Accordingly, the testing time for testing a set of circuits via the ATE 102 can be significantly reduced, thereby allowing for significantly greater efficiency in testing a set of DUTs 104.

FIG. 2 is an example block diagram of a DUT 200. The DUT 200 can correspond to a circuit that is one of the DUTs 104 that is tested by the ATE 102 in the example of FIG. 2. Therefore, reference is to be made to the example of FIG. 1 in the following description of the example of FIG. 2.

The DUT 200 includes a circuit core 202, a bidirectional switching control network 204, and a plurality N of bidirectional I/O circuits 206, where N is a positive integer greater than one. In addition to the bidirectional I/O circuits 206, the DUT 200 includes additional terminals, including a power terminal 208 to receive an input voltage VIN (e.g., from the DPS 112), as well as a set of terminals associated with testing the DUT 200. In the example of FIG. 2, in implementing the IEEE 1149.1 JTAG testing protocol, the testing terminals are demonstrated as a TMS terminal 210 that receives a scan enable signal SE or a dedicated scan enable signal SE or a shared scan enable signal SE with any general purpose I/O or plural of scan enable signals SE, a TCK terminal 212 that receives a scan clock signal SCK or a dedicated scan clock signal SCK or a shared scan clock signal SCK with any general purpose I/O or plurality of scan clock signals SCK, a TDI scan input terminal 214 or a dedicated scan data input TDI or a shared scan data input TDI with any general purpose I/O or plural of scan data inputs TDI that corresponds to a scan-in input to receive a set of SoC scan data to the DUT 200, and a TDO scan output terminal 216 or a dedicated scan data output TDO or a shared scan data output TDO with any general purpose I/O or plural of scan data output TDO that corresponds to a scan-out output to shift out the set of SoC scan data from the DUT 200. The TDI scan input terminal 214 and the TDO scan output terminal 216 are coupled to scan chain registers 218 that propagate the set of SoC scan data, demonstrated as a signal SCN, to the circuit core 202 and to each of the bidirectional I/O circuits 206. While the examples described herein are provided in the context of JTAG testing, other testing protocols and formats can be implemented that implement a scan-chain for testing.

The circuit core 202 is configured to provide an operational function for the DUT 200. In the example of FIG. 2, the circuit core 202 is coupled to each of the bidirectional I/O circuits 206 via a set of signals CC for performing the operational function via the bidirectional I/O circuits 206. Each of the bidirectional I/O circuits 206 includes an I/O pad 220, a bidirectional I/O control (“I/O CONTROL”) 222, and testing logic 224. The I/O pad 220 of each of the bidirectional I/O circuits 206 can be coupled to I/O pins of the package associated with the DUT 200, demonstrated in the example of FIG. 2 as terminals labeled “I/O 1” through “I/O N”. The bidirectional I/O control 222 of each of the bidirectional I/O circuits 206 can control a mode (e.g., input mode or output mode) that dictates whether the I/O pad 220 can be implemented for receiving input signals or providing output signals. Thus, the circuit core 202 can be configured to receive input signals provided to the I/O pad 220 of one or more of the bidirectional I/O circuits 206 in which the respective bidirectional I/O control 222 is set for the input mode, and can process the input signals to provide output signals to the I/O pad 220 of one or more other bidirectional I/O circuits 206 in which the respective bidirectional I/O control 222 is set for the output mode during a normal operating mode, with such input and output signals to and from the circuit core 202 being represented by the signals CC.

During testing of the DUT 200, the set of SoC scan data SCN is input via the TDI scan input terminal 214 to the scan chain registers 218 and shifted through the scan chain registers via the scan enable signal SE and the scan clock signal SCK to an initial device state of the DUT 200. As an example, the testing logic 224 can include multiplexers that are configured to set the bidirectional I/O circuits 206 into a testing mode, thereby disconnecting the bidirectional I/O control 222 from the circuit core 202 and coupling the bidirectional switching control network 204 and a portion of the testing logic 224 (e.g., a sense and drive-back network, as described in greater detail herein) to the bidirectional I/O control 222. Therefore, in the testing mode, the bidirectional switching control network 204 and the testing logic 224 can be configured to facilitate complete input and output parametric testing on the respective I/O pad 220 of each of the bidirectional I/O circuits 206, as well as a quiescent current measurement test via the power terminal 208, on the single set of SoC scan data.

In the example of FIG. 2, the bidirectional switching control network 204 provides a switching signal SW to each of the respective bidirectional I/O circuits 206. Beginning at initial device state, the scan enable signal SE and the scan clock SCK can iteratively shift the set of SoC scan data SCN, thereby changing the device state of the DUT 200 at each shift of the SoC scan data SCN. At each shift of the SoC scan data SCN, the switching signal SW provided from the bidirectional switching control network 204 can change state to alternately switch the bidirectional I/O control 222 of each of the respective bidirectional I/O circuits 206 between the input mode and the output mode. Thus, in a first shift load of the SoC scan data SCN, the bidirectional switching control network 204 can provide the switching signal SW to set the bidirectional I/O control 222 of each of the bidirectional I/O circuits 206 to the input mode, such that the testing logic 224 can facilitate an input parametric test of the respective I/O pad 220. In a first capture followed by an extra shift cycle of the SoC scan data SCN, the bidirectional switching control network 204 can provide the switching signal SW to set the bidirectional I/O control 222 of each of the bidirectional I/O circuits 206 to the output mode, such that the testing logic 224 can facilitate an output parametric test of the respective I/O pad 220. As an example, each of the input and output parametric tests can be one of a high or low parametric test, such that the other of the high or low parametric tests can be provided at each of a third and fourth shift and capture of the SoC scan data SCN. Accordingly, at only four shift cycles and four capture cycles of a single set of the SoC scan data SCN, the entirety of parametric tests can be performed on the DUT 200.

As another example, the testing logic 224 can also include pull-up and pull-down testing logic. Therefore, the bidirectional switching control network 204 and the testing logic 224 can operate to perform pull-up and pull-down testing (e.g., via the PPMU 106) of the I/O pad 220 of each of the bidirectional I/O circuits 206 at additional respective shift and capture cycles of the single set of SoC scan data SCN in addition to the input high, input low, output high, and output low parametric tests. Furthermore, as described above, the power terminal 208 can be coupled to a DPS (e.g., the DPS 112). Therefore, the ATE 102 can further provide a quiescent current test at each shift of the SoC scan data SCN concurrently with the parametric tests, as well as the pull-up and pull-down tests, of the I/O pad 220 of each of the bidirectional

I/O circuits 206. Accordingly, the bidirectional switching control network 204 and the testing logic 224 of each of the bidirectional I/O circuits 206 can facilitate the input and output parametric testing concurrently with each other and with the quiescent current measurement test of the power terminal 208 for each device state of the DUT 200 on a single set of the SoC scan data SCN. As a result, testing of the DUT 200 can be performed more efficiently by obviating the need to provide multiple separate scan loads to and from the DUT 200 to provide each individual input and output parametric tests, as well as for separate quiescent current tests.

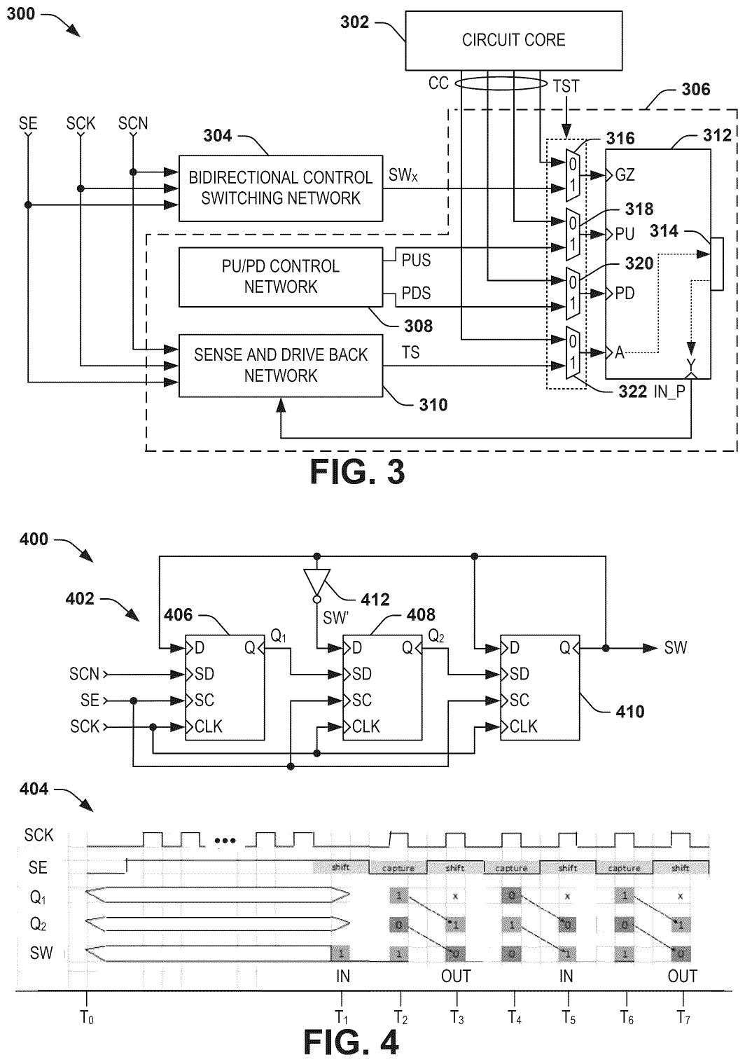

FIG. 3 is an example of a bidirectional I/O test system 300. The bidirectional I/O test system 300 includes a circuit core 302, a bidirectional switching control network 304, and a bidirectional I/O circuit 306. The circuit core 302 can correspond to the circuit core 202, the bidirectional switching control network 304 can correspond to the bidirectional switching control network 204, and the bidirectional I/O circuit 306 can correspond to one of the bidirectional I/O circuits 206. Therefore, reference is to be made to the example of FIG. 2 in the following description of the example of FIG. 3.

The bidirectional I/O circuit 306 includes a pull-up/pull-down control network (“PU/PD CONTROL NETWORK”) 308, a sense and drive-back network 310, a bidirectional I/O control 312, and an I/O pad 314. The pull-up/pull-down control network 308 and the sense and drive-back network 310 can collectively correspond to the testing logic 224. The bidirectional I/O control 312 includes a GZ input that controls whether the bidirectional I/O control 312 is in the input mode (e.g., in response to receiving a logic-1) or the output mode (e.g., in response to receiving a logic-0), a PU input that is implemented for pull-up testing, a PD input that is implemented for pull-down testing, an A input for providing data from the core to the I/O pad 314, and a Y output for providing data from the I/O pad 314 to the circuit core 202, demonstrated as a signal IN_P.

The bidirectional I/O circuit 306 also includes a set of multiplexers. A first multiplexer 316 provides an output to the GZ input of the bidirectional I/O control 312, a second multiplexer 318 provides an output to the PU input of the bidirectional I/O control 312, a third multiplexer 320 provides an output to the PD input of the bidirectional I/O control 312, and a fourth multiplexer 322 provides an output to the A input of the bidirectional I/O control 312. Each of the multiplexers 316 includes a first input that is provided a signal CC from the circuit core 302. The first multiplexer 316 receives the switching signal SW from the bidirectional switching control network 304 at a second input, the second multiplexer 318 receives a pull-up signal PUS from the pull-up/pull/down control network 308 at a second input, the third multiplexer 320 receives a pull-down signal PUD from the pull-up/pull-down control network 308 at a second input, and the fourth multiplexer 322 receives a test signal TS from the sense and drive-back network 310. The multiplexers 316, 318, 320, and 322 are each configured to receive a test signal TST that is configured to switch the multiplexers 316, 318, 320, and 322 from the first input in the normal operating mode to the second input in the test mode.

The bidirectional switching control network 304 and the sense and drive-back network 310 are each configured to receive the set of SoC scan data SCN, the scan clock SCK, and the scan enable signal SE as inputs. As described in greater detail herein, the bidirectional switching control network 304 and the sense and drive-back network 310 are configured to cooperate to facilitate the concurrent input and output parametric testing on the set of SoC scan data SCN, as well as to facilitate the quiescent current measurement test concurrently with the parametric testing, based on shifting bits the set of SoC scan data SCN through the bidirectional switching control network 304 and the sense and drive-back network 310. For example, the bidirectional switching control network 304 is configured to alternate the state of the switching signal SW at each shift cycle followed by capture cycle of the set of SoC scan data SCN to alternate the state of the bidirectional I/O control 312 between the input mode and the output mode, as described in greater detail in the example of FIG. 4.

As demonstrated in the example of FIG. 2, the bidirectional switching control network 204 is common or shared or can be dedicated to each of the bidirectional I/O circuits 206. Therefore, the bidirectional switching control network 304 in the example of FIG. 3 is demonstrated as providing the switching signal SW to the respective bidirectional I/O circuit 306. However, the bidirectional switching control network 304 can also provide the switching signal SW to each of the other bidirectional I/O circuits 206 (e.g., each being arranged similar to or the same as the bidirectional I/O circuit 306) to control the mode (e.g., input mode or output mode) of the bidirectional I/O control 312 of each of the bidirectional I/O circuits 306.

FIG. 4 is an example diagram 400 of a bidirectional switching control network 402. The diagram 400 also includes a timing diagram 404 that demonstrates the operation of the bidirectional switching control network 402. The bidirectional switching control network 402 can correspond to the bidirectional switching control network 204 and/or the bidirectional switching control network 304 in the respective examples of FIGS. 2 and 3. Therefore, reference is to be made to the example of FIGS. 2 and 3 in the following description of the example of FIG. 4.

The bidirectional switching control network 402 includes a first latching device 406, a second latching device 408, and a third latching device 410. The latching devices 406, 408, and 410 are each demonstrated in the example of FIG. 4 as flip-flops. However, any of a variety of storage elements that can provide shift, capture and storage of data can be implemented instead of flip-flops. Each of the latching devices 406, 408, and 410 includes a D input, an SD input, an SC input, a CLK (e.g., clock) input, and a Q output.

Each of the latching devices 406, 408, and 410 is demonstrated as receiving the scan enable signal SE at the SC input and the scan clock signal SCK at the CLK input. The first latching device 406 is demonstrated as receiving the SoC scan data SCN at the SD input and providing a signal Q₁ at the Q output. The second latching device 408 is demonstrated as receiving the signal Q₁ provided from the Q output of the first latching device 406 at the respective SD input, and is also demonstrated as providing a signal Q₂ at the respective Q output. The third latching device 410 is demonstrated as receiving the signal Q₂ provided from the Q output of the second latching device 408 at the respective SD input, and is also demonstrated as providing the switching signal SW at the respective Q output. In the example of FIG. 4, the switching signal SW is provided as feedback to the D input of each of the latching devices 406, 408 (via an inverter 412 as an inverted switching signal SW′), and 410. As described above, the switching signal SW is also provided to each of the bidirectional I/O circuits 206 in the DUT 200 to alternately switch the respective bidirectional I/O control 312 of the bidirectional I/O circuit 306 (e.g., each of the bidirectional I/O circuits 206) between the input mode and the output mode via the GZ input of the bidirectional I/O control 312.

As described above, the set of SoC scan data SCN is input via the TDI scan input terminal 214 of the DUT 200 and shifted through the scan chain registers 218 via the scan enable signal SE and the scan clock signal SCK to an initial device state of the DUT 200. The shifting of the SoC scan data SCN to the initial device state is demonstrated in the timing diagram 404 beginning at a time T₀, in which the scan enable signal SE is asserted and the scan clock signal SCK is repeatedly cycled. In response to assertion of the scan enable signal SE, the latching devices 406, 408, and 410 provide the SD input at the Q output, as opposed to providing the D input at the Q output in response to de-assertion of the scan enable signal SE. Therefore, beginning at the time T₀, at each period of the scan clock signal SCK, one bit of the SoC scan data SCN is provided to the SD input of the first latching device 406, the signal Q₁ is provided as the signal Q₂, and the signal Q₂ is provided as the switching signal SW until the initial device state is attained at a time T₁. As an example, the initial device state of the DUT 200 can be predefined such that the switching signal SW can be provided as a logic high (or as required), thereby setting the bidirectional I/O control 312 to the input mode, where the mode is demonstrated at the time T₁ as “IN”, in the initial device state of the DUT 200.

Beginning at a time T₂, the bidirectional switching control network 402 alternates between a capture phase and a shift phase, where “capture phase” corresponds to setting a value of the output signal Q₁ to be equal to the switching signal SW, and “shift phase” corresponds to a single bit shift of the set of SoC scan data SCN into the bidirectional switching control network 402 (e.g., via the SD input of the first latching device 406). At the time T₂, the bidirectional switching control network 402 is in a capture phase in which the scan enable signal SE is de-asserted and the scan clock signal CLK is cycled. As a result, the logic-1 state of the switching signal SW that is provided to the D input of the first latching device 406 is provided as the output signal Q₁ and is provided to the D input of the third latching device 410 to maintain the logic-1 state of the switching signal SW, as output from the Q output of the third latching device 410. The logic high (or as required) state of the switching signal SW is also inverted via the inverter 412 as the signal SW′ provided to the D input of the second latching device 408 to provide the output signal Q₂ from the second latching device 408 as a logic low (or as required).

At a time T₃, the bidirectional switching control network 402 is in a shift phase in which the scan enable signal SW is asserted and the scan clock signal SCK is cycled. As a result, the set of SoC scan data SCN is shifted by a single bit in the shift phase. As a result, a next bit of the SoC scan data SCN having an arbitrary logic state X is shifted into the SD input of the first latching device 406, thereby providing the output signal Q₁ to have the logic state X. The previous output signal Q₁, having the logic high (or as required) state in the capture phase, is shifted into the SD input of the second latching device 408 at the time T₃, thereby switching the logic state of the output signal Q₂ to a corresponding logic high (or as required) state. Similarly, the previous output signal Q₂, having the logic low (or as required) state in the capture phase, is shifted into the SD input of the third latching device 410 at the time T₃, thereby switching the logic state of the switching signal SW to a corresponding logic low (or as required) state. The switching of the logic state of the output signal Q₁ in the capture phase to the output signal Q₂ in the shift phase, and the switching of the logic state of the output signal Q₂ in the capture phase to the switching signal SW in the shift phase, is demonstrated by arrows 414 between the times T₂ and T₃. Therefore, after the shift phase at the time T₃, and thus after a shift of the set of SoC scan data SCN, the bidirectional switching control network 402 sets the bidirectional I/O control 312 to the output mode via the GZ input, where the mode is demonstrated at the time T₃ as “OUT”.

At the time T₄, the bidirectional switching control network 402 returns to a capture phase in which the scan enable signal SE is de-asserted and the scan clock signal CLK is cycled. As a result, the logic low (or as required) state of the switching signal SW that is provided to the D input of the first latching device 406 is provided as the output signal Q₁, and is provided to the D input of the third latching device 410 to maintain the logic low (or as required) state of the switching signal SW, as output from the Q output of the third latching device 410. The logic low (or as required) state of the switching signal SW is also inverted via the inverter 412 as the signal SW′ provided to the D input of the second latching device 408 to provide the output signal Q₂ from the second latching device 408 as a logic high (or as required).

At a time T₅, the bidirectional switching control network 402 returns to a shift phase in which the scan enable signal SW is asserted and the scan clock signal SCK is cycled. As a result, the set of SoC scan data SCN is shifted by another single bit in the shift phase. As a result, a next bit of the SoC scan data SCN having an arbitrary logic state X is shifted into the SD input of the first latching device 406, thereby providing the output signal Q₁ to have the logic state X. The previous output signal Q₁, having the logic low (or as required) state in the capture phase, is shifted into the SD input of the second latching device 408 at the time T₅, thereby switching the logic state of the output signal Q₂ to a corresponding logic low (or as required) state. Similarly, the previous output signal Q₂, having the logic high (or as required) state in the capture phase, is shifted into the SD input of the third latching device 410 at the time T₅, thereby switching the logic state of the switching signal SW to a corresponding logic high (or as required) state. The switching of the logic state of the output signal Q₁ in the capture phase to the output signal Q₂ in the shift phase, and the switching of the logic state of the output signal Q₂ in the capture phase to the switching signal SW in the shift phase, is demonstrated by arrows 416 between the times T₄ and T₅. Therefore, after the shift phase at the time T₅, and thus after another shift of the set of SoC scan data SCN, the bidirectional switching control network 402 sets the bidirectional I/O control 312 to the input mode via the GZ input, where the mode is demonstrated at the time T₅ as “IN”.

At the time T₆, the bidirectional switching control network 402 returns to a capture phase in which the scan enable signal SE is de-asserted and the scan clock signal CLK is cycled. As a result, the logic high (or as required) state of the switching signal SW that is provided to the D input of the first latching device 406 is provided as the output signal Q₁, and is provided to the D input of the third latching device 410 to maintain the logic high (or as required) state of the switching signal SW, as output from the Q output of the third latching device 410. The logic high (or as required) state of the switching signal SW is also inverted via the inverter 412 as the signal SW′ provided to the D input of the second latching device 408 to provide the output signal Q₂ from the second latching device 408 as a logic low (or as required).

At a time T₇, the bidirectional switching control network 402 returns to a shift phase in which the scan enable signal SW is asserted and the scan clock signal SCK is cycled. As a result, the set of SoC scan data SCN is shifted by another single bit in the shift phase. As a result, a next bit of the SoC scan data SCN having an arbitrary logic state X is shifted into the SD input of the first latching device 406, thereby providing the output signal Q₁ to have the logic state X. The previous output signal Q₁, having the logic high (or as required) state in the capture phase, is shifted into the SD input of the second latching device 408 at the time T₇, thereby switching the logic state of the output signal Q₂ to a corresponding logic high (or as required) state. Similarly, the previous output signal Q₂, having the logic low (or as required) state in the capture phase, is shifted into the SD input of the third latching device 410 at the time T₇, thereby switching the logic state of the switching signal SW to a corresponding logic low (or as required) state. The switching of the logic state of the output signal Q₁ in the capture phase to the output signal Q₂ in the shift phase, and the switching of the logic state of the output signal Q₂ in the capture phase to the switching signal SW in the shift phase, is demonstrated by arrows 418 between the times T₆ and T₇. Therefore, after the shift phase at the time T₇, and thus after another shift of the set of SoC scan data SCN, the bidirectional switching control network 402 sets the bidirectional I/O control 312 to the output mode via the GZ input, where the mode is demonstrated at the time T₇ as “OUT”.

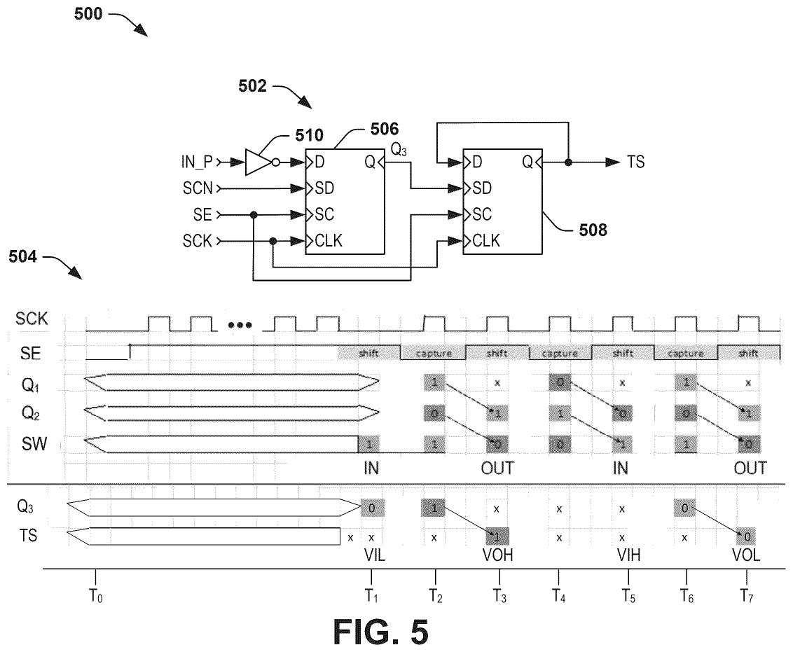

At each mode change of the bidirectional I/O control 312, the ATE 102 can perform a corresponding respective parametric test of the I/O pad 314 of each of the bidirectional I/O circuits 306. For example, in the input mode, the ATE 102 can perform an input parametric test by providing an input signal (e.g., a logic-high for a voltage/current high input parametric test or a logic-low for a voltage/current low input parametric test) to the I/O pad 314. Similarly, in the output mode, the ATE 102 can perform an output parametric test by receiving an output signal (e.g., a logic-high for a voltage/current high output parametric test or a logic-low for a voltage/current low output parametric test) from the I/O pad 314. As an example, the ATE 102 can alternate between logic high and logic low parametric tests in each of the input mode and the output mode, thereby alternating between a voltage input low test at the respective I/O pad 314 at the time T₁, a voltage output high test at the respective I/O pad 314 at the time T₃, a voltage input high test at the respective I/O pad 314 at the time T₅, and a voltage output low test at the respective I/O pad 314 at the time T₇, as described in greater detail in the example of FIG. 5.

FIG. 5 is an example diagram 500 of a sense and drive-back network 502. The diagram 500 also includes the timing diagram 404 that demonstrates the operation of the bidirectional switching control network 402, replicated in the example of FIG. 5 for convenience of explanation, and a timing diagram 504 that demonstrates the operation of the sense and drive-back network 502. The timing diagrams 404 and 504 are demonstrated as coterminous in time. The sense and drive-back network 502 can correspond to the sense and drive-back network 310 in the example of FIG. 3, in cooperation with the bidirectional switching control network 402 in the example of FIG. 4. Therefore, reference is to be made to the example of FIGS. 3 and 4 in the following description of the example of FIG. 5.

The sense and drive-back network 502 includes a first latching device 506 and a second latching device 508. The latching devices 506 and 508 are each demonstrated in the example of FIG. 5 as flip-flops. However, any of a variety of storage elements that can provide shift, capture and storage of data can be implemented instead of flip-flops. Each of the latching devices 506 and 508 includes a D input, an SD input, an SC input, a CLK (e.g., clock) input, and a Q output.

Each of the latching devices 506 and 508 is demonstrated as receiving the scan enable signal SE at the SC input and the scan clock signal SCK at the CLK input. The first latching device 506 is demonstrated as receiving the SoC scan data SCN at the SD input and providing a signal Q₃ at the Q output. The second latching device 508 is demonstrated as receiving the signal Q₃ provided from the Q output of the first latching device 506 at the respective SD input, and is also demonstrated as providing the test signal TS at the respective Q output. In the example of FIG. 5, the test signal TS is provided as feedback to the D input of the second latching device 508. As also demonstrated in the example of FIG. 5, the signal IN_P provided from the Y output of the bidirectional I/O control 312 is provided to the D input of the first latching device 506 via an inverter 510 (by example). As described above, the test signal TS is provided to the A input the bidirectional I/O control 312 of the respective one of the bidirectional I/O circuits 306 in the DUT 200 to provide an output signal in an output parametric test in the output mode.

As described above, the set of SoC scan data SCN is input via the TDI scan input terminal 214 of the DUT 200 and shifted through the scan chain registers 218 via the scan enable signal SE and the scan clock signal SCK to an initial device state of the DUT 200. The shifting of the SoC scan data SCN to the initial device state is demonstrated in the timing diagram 504 beginning at the time T₀, in which the scan enable signal SE is asserted and the scan clock signal SCK is repeatedly cycled. In response to assertion of the scan enable signal SE, the latching devices 506 and 508 provide the SD input at the Q output, as opposed to providing the D input at the Q output in response to de-assertion of the scan enable signal SE. Therefore, beginning at the time T₀, at each period of the scan clock signal SCK, one bit of the SoC scan data SCN is provided to the SD input of the first latching device 506 and the signal Q₃ is provided as the timing signal TS until the initial device state is attained at the time T₁. As an example, the initial device state of the DUT 200 can be predefined such that the first latching device 506 receives a logic low (or as required) signal from the SoC scan data SCN, thereby providing the output signal Q₃ as having a logic low (or as required) at the time T₁.

As described above, at the time T₁, the bidirectional I/O control 312 is set to the input mode “IN”. Therefore, as an example, the PPMU 106 of the ATE 102 can provide an input parametric test at the I/O pad 314. In the example of FIG. 5, the input parametric test can be a voltage/current input low test, demonstrated as “VIL” at the time T₁. Therefore, the PPMU 106 can provide a logic low (or as required) input to the I/O pad 314, which can be provided to the circuit core 202 via the signal IN_P from the Y output of the bidirectional I/O control 312, such as to be recorded as part of the SoC scan data SCN that is output from the TDO scan output terminal 216 at the conclusion of the testing of the DUT 200. In addition, at the time T₁ in the initial device state, the test signal TS is at an arbitrary value X based on the bit of the SoC scan data SCN preceding the logic low (or as required) bit of the SoC scan data SCN provided as the output signal Q₃. The X logic-state of the test signal TS is irrelevant, however, given that the bidirectional I/O control 312 is set for the input mode at the time T₁.

Beginning at the time T₂, concurrently with the bidirectional switching control network 402, the sense and drive-back network 502 alternates between a capture phase and a shift phase, where “capture phase” corresponds to setting a value of the output signal Q₃ to be a complement of the signal IN_P provided from the Y output of the bidirectional I/O control 312, and “shift phase” corresponds to a single bit shift of the set of SoC scan data SCN into the sense and drive-back network 502 (e.g., via the SD input of the first latching device 506). At the time T₂, the sense and drive-back network 502 is in a capture phase in which the scan enable signal SE is de-asserted and the scan clock signal CLK is cycled. As a result, the logic low (or as required) state of the signal IN_P that is provided from the Y output of the bidirectional I/O control 312 is provided as a logic high (or as required) via the inverter 510 to the D input of the first latching device 506.

At the time T₃, the sense and drive-back network 502 is in a shift phase in which the scan enable signal SW is asserted and the scan clock signal SCK is cycled. As a result, the set of SoC scan data SCN is shifted by a single bit in the shift phase. As a result, a next bit of the SoC scan data SCN having an arbitrary logic state X is shifted into the SD input of the first latching device 506, thereby providing the output signal Q₃ to have the arbitrary logic state X. The previous output signal Q₃, having the logic high (or as required) state in the capture phase, is shifted into the SD input of the second latching device 508 at the time T₃, thereby switching the logic state of the test signal TS to a corresponding logic high (or as required) state. The switching of the logic state of the output signal Q₃ in the capture phase to the test signal TS in the shift phase is demonstrated by arrow 512 between the times T₂ and T₃.

As described above, after the shift phase at the time T₃, and thus after a shift of the set of SoC scan data SCN, the bidirectional I/O control 312 is set to the output mode “OUT”. Therefore, at the time T₃, as an example, the PPMU 106 of the ATE 102 can provide an output parametric test from the I/O pad 314. In the example of FIG. 5, the output parametric test can be a voltage output high (or as required) test, demonstrated as “VOH” at the time T₃. Therefore, the sense and drive-back network 502 provides a logic high (or as required) to the A input of the bidirectional I/O control 312, such that the logic high (or as required) is provided as output from the I/O pad 314. The PPMU 106 can therefore receive and record (e.g., via the memory 110) the logic high (or as required) provided from the I/O pad 314 as the voltage output high parametric test.

At the time T₄, the sense and drive-back network 502 returns to a capture phase in which the scan enable signal SE is de-asserted and the scan clock signal CLK is cycled. As a result, an arbitrary logic state X is provided to the D input of the first latching device 506, and the arbitrary logic state X is provided from the output signal Q₃ to the SD input of the second latching device 508, thereby providing the arbitrary logic state X as the test signal TS. At the time T₅, the sense and drive-back network 502 returns to a shift phase in which the scan enable signal SW is asserted and the scan clock signal SCK is cycled. As a result, the set of SoC scan data SCN is shifted by another single bit in the shift phase. As a result, a next bit of the SoC scan data SCN having an arbitrary logic state X is shifted into the SD input of the first latching device 506, thereby providing the output signal Q₃ to have the logic state X. The previous output signal Q₃, likewise having an arbitrary logic state X, is shifted into the SD input of the second latching device 508 at the time T₅, thereby switching the logic state of the test signal SD to the arbitrary logic state X.

As described above, at the time T₅, the bidirectional I/O control 312 is set to the input mode “IN”. Therefore, as an example, the PPMU 106 of the ATE 102 can provide an input parametric test at the I/O pad 314. In the example of FIG. 5, the input parametric test can be a voltage input high (or as required) test, demonstrated as “VIH” at the time T₅. Therefore, the PPMU 106 can provide a logic high (or as required) input to the I/O pad 314, which can be provided to the circuit core 202 via the signal IN_P from the Y output of the bidirectional I/O control 312, such as to be recorded as part of the SoC scan data SCN that is output from the TDO scan output terminal 216 at the conclusion of the testing of the DUT 200. In addition, at the time T₅, the X logic-state of the test signal TS is irrelevant given that the bidirectional I/O control 312 is set for the input mode.

At the time T₆, the sense and drive-back network 502 is in a capture phase in which the scan enable signal SE is de-asserted and the scan clock signal CLK is cycled. As a result, the logic high (or as required) state of the signal IN_P that is provided from the Y output of the bidirectional I/O control 312 is provided as a logic low (or as required) via the inverter 510 to the D input of the first latching device 506. At the time T₇, the sense and drive-back network 502 is in a shift phase in which the scan enable signal SW is asserted and the scan clock signal SCK is cycled. As a result, the set of SoC scan data SCN is shifted by a single bit in the shift phase. As a result, a next bit of the SoC scan data SCN having an arbitrary logic state X is shifted into the SD input of the first latching device 506, thereby providing the output signal Q₃ to have the arbitrary logic state X. The previous output signal Q₃, having the logic low (or as required) state in the capture phase, is shifted into the SD input of the second latching device 508 at the time T₇, thereby switching the logic state of the test signal TS to a corresponding logic low (or as required) state. The switching of the logic state of the output signal Q₃ in the capture phase to the test signal TS in the shift phase is demonstrated by arrow 514 between the times T₆ and T₇.

As described above, after the shift phase at the time T₇, and thus after a shift of the set of SoC scan data SCN, the bidirectional I/O control 312 is set to the output mode “OUT”. Therefore, at the time T₇, as an example, the PPMU 106 of the ATE 102 can provide an output parametric test from the I/O pad 314. In the example of FIG. 5, the output parametric test can be a voltage output low (or as required) test, demonstrated as “VOL” at the time T₇. Therefore, the sense and drive-back network 502 provides a logic low (or as required) to the A input of the bidirectional I/O control 312, such that the logic low (or as required) is provided as output from the I/O pad 314. The PPMU 106 can therefore receive and record (e.g., via the memory 110) the logic-0 provided from the I/O pad 314 as the voltage output low parametric test.

FIG. 5 therefore demonstrates the manner in which the bidirectional switching control network 402 and the sense and drive-back network 502 of each of the bidirectional I/O circuits 306 cooperates to provide concurrent input and output parametric tests on the same set of SoC scan data SCN. As also described herein, the bidirectional switching control network 402 and the sense and drive-back network 502 of each of the bidirectional I/O circuits 306 can also cooperate to facilitate concurrent pull-up and pull-down testing of each of the bidirectional I/O circuits 306 via the PPMU 106, as well as the quiescent current measurement test of the power terminal 208 via the DPS 112.

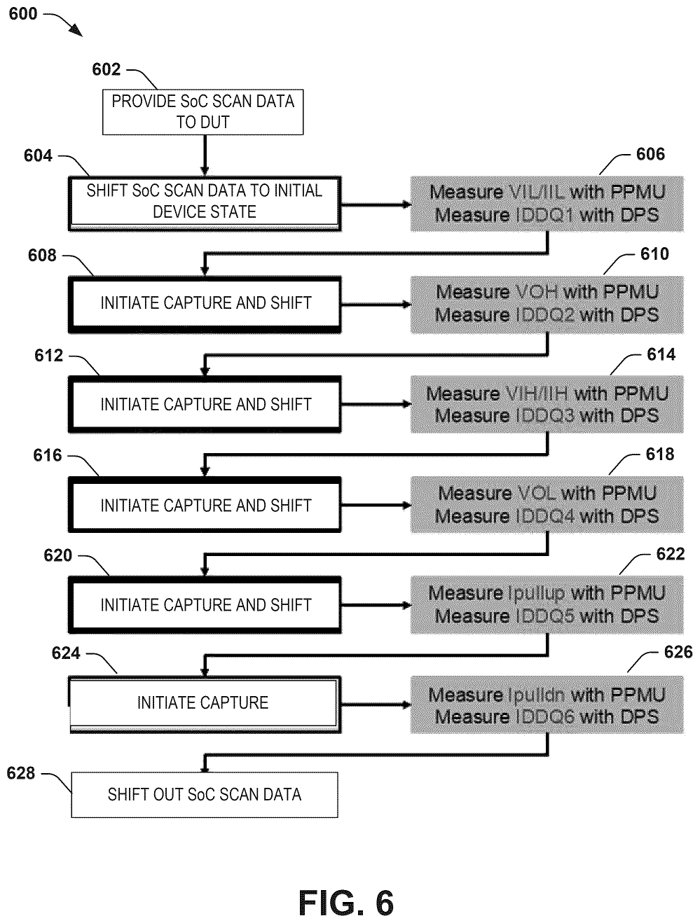

FIG. 6 is an example diagram of a testing process 600. The testing process 600 demonstrates an example of the sequence of complete parametric and the quiescent current measurement test of the DUT 200. Therefore, reference is to be made to the examples of FIGS. 2-5 in the following description of the example of FIG. 6.

The testing process 600 begins at 602. At 602, the set of SoC scan data is provided to the DUT 200 (e.g., provided as an input to the TDI scan input terminal 214). At 604, the set of SoC scan data is shifted via the scan enable signal SE and the scan clock signal SCK to provide an initial device state for the DUT 200. As an example, the initial device state can be such that the third latching device 410 of the bidirectional switching control network 402 is set to provide the switching signal SW at a logic-1, and such that the first latching device 506 of the sense and drive-back network 502 is set to provide the output signal Q₃ at a logic-0 state. At 604, in the initial device state set at 602, the bidirectional I/O control 312 of each of the bidirectional I/O circuits 306 can be set to the input mode (e.g., at the time T₁). Therefore, the ATE 102 can provide a voltage input low parametric test via the PPMU 106. Additionally, the ATE 102 can provide a concurrent quiescent current (“IDDQ1”) test at 604 via the power terminal 208, thereby determining the presence of a quiescent current in the DUT 200 in the initial device state.

At 606, the bidirectional switching control network 402 and the sense and drive-back network 502 initiate a capture and shift by alternating between a capture phase (e.g., at the time T₂) and a shift phase (e.g., at the time T₃) by providing a single shift of the set of SoC scan data. Therefore, at 608, the bidirectional I/O control 312 of each of the bidirectional I/O circuits 306 can be set to the output mode (e.g., at the time T₃). Accordingly, the ATE 102 can provide a voltage output high parametric test via the PPMU 106. Additionally, the ATE 102 can provide a concurrent quiescent current (“IDDQ2”) test at 608 via the power terminal 208, thereby determining the presence of a quiescent current in the DUT 200 in the new device state corresponding to the shift of the set of SoC scan data.

At 610, the bidirectional switching control network 402 and the sense and drive-back network 502 initiate a capture and shift by alternating between a capture phase (e.g., at the time T₄) and a shift phase (e.g., at the time T₅) by providing a single shift of the set of SoC scan data. Therefore, at 612, the bidirectional I/O control 312 of each of the bidirectional I/O circuits 306 can be set to the input mode (e.g., at the time T₅). Accordingly, the ATE 102 can provide a voltage input high parametric test via the PPMU 106. Additionally, the ATE 102 can provide a concurrent quiescent current (“IDDQ3”) test at 612 via the power terminal 208, thereby determining the presence of a quiescent current in the DUT 200 in the new device state corresponding to the shift of the set of SoC scan data.

At 614, the bidirectional switching control network 402 and the sense and drive-back network 502 initiate a capture and shift by alternating between a capture phase (e.g., at the time T₆) and a shift phase (e.g., at the time T₇) by providing a single shift of the set of SoC scan data. Therefore, at 616, the bidirectional I/O control 312 of each of the bidirectional I/O circuits 306 can be set to the output mode (e.g., at the time T₇). Accordingly, the ATE 102 can provide a voltage output low parametric test via the PPMU 106. Additionally, the ATE 102 can provide a concurrent quiescent current (“IDDQ4”) test at 616 via the power terminal 208, thereby determining the presence of a quiescent current in the DUT 200 in the new device state corresponding to the shift of the set of SoC scan data.

At 618, the bidirectional switching control network 402 and the sense and drive-back network 502 initiate a capture and shift by alternating between a capture phase and a shift phase (e.g., subsequent to the time T₇) by providing a single shift of the set of SoC scan data. Therefore, at 620, the bidirectional I/O control 312 of each of the bidirectional I/O circuits 306 can be set to the input mode. Accordingly, the ATE 102 can provide a pull-up (“Ipullup”) test via the PPMU 106. For example, the PPMU 106 can provide a logic-high signal at the I/O pad 314 while the pull-up/pull-down control network 308 can provide a logic-low signal to the PU input of the bidirectional I/O control 312. Additionally, the ATE 102 can provide a concurrent quiescent current (“IDDQ5”) test at 620 via the power terminal 208, thereby determining the presence of a quiescent current in the DUT 200 in the new device state corresponding to the shift of the set of SoC scan data during the pull-up test.

At 622, the bidirectional switching control network 402 and the sense and drive-back network 502 initiate a capture phase without providing a shift phase. Therefore, at 624, the bidirectional I/O control 312 of each of the bidirectional I/O circuits 306 can remain set to the input mode. Accordingly, the ATE 102 can provide a pull-down (“Ipulldn”) test via the PPMU 106. For example, the PPMU 106 can provide a logic-low signal at the I/O pad 314 while the pull-up/pull-down control network 308 can provide a logic-high signal to the PD input of the bidirectional I/O control 312. Additionally, the ATE 102 can provide a concurrent quiescent current (“IDDQ6”) test at 620 via the power terminal 208, thereby determining the presence of a quiescent current in the DUT 200 in the device state corresponding to the shift of the set of SoC scan data during the pull-down test.

At 624, the single set of SoC scan data is shifted out of the DUT 200, such that the SoC scan data is output from the TDO scan output terminal 216. At 624, the entirety of the parametric and quiescent current measurement test is therefore concluded. Therefore, the testing process 600 demonstrates the manner in which input and output parametric testing can be performed concurrently on the single set of SoC scan data, which can also be performed concurrently with the quiescent current measurement test. Accordingly, the testing process 600 demonstrates a significantly more efficient manner of testing the DUT 200 in which multiple sets of SoC scan data are required to be scanned in and out of the DUT 200 for each dedicated performance of input and output parametric testing, as well as dedicated quiescent current measurement test. The significant time savings of the testing of the DUT 200 can thus realize significant reductions in the expense of testing multiple DUTs for operational performance.

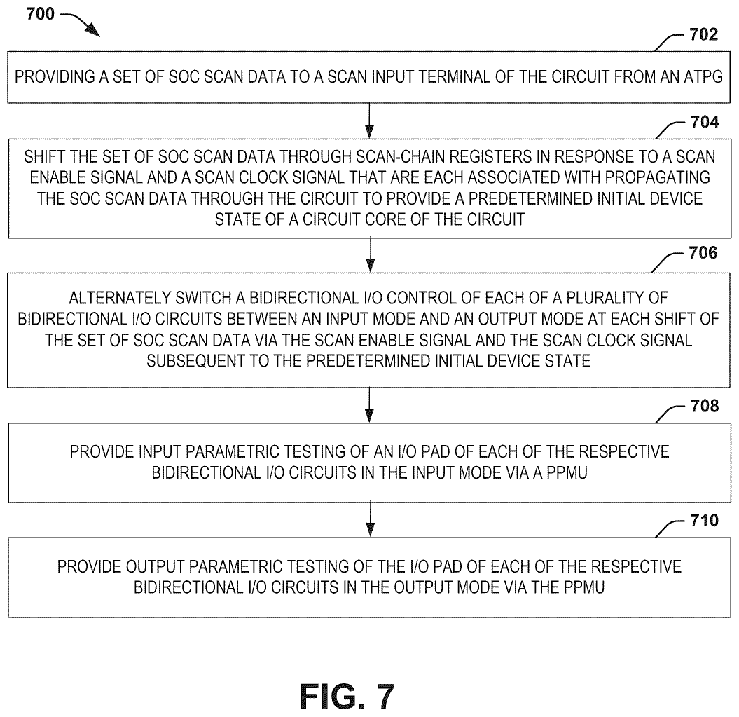

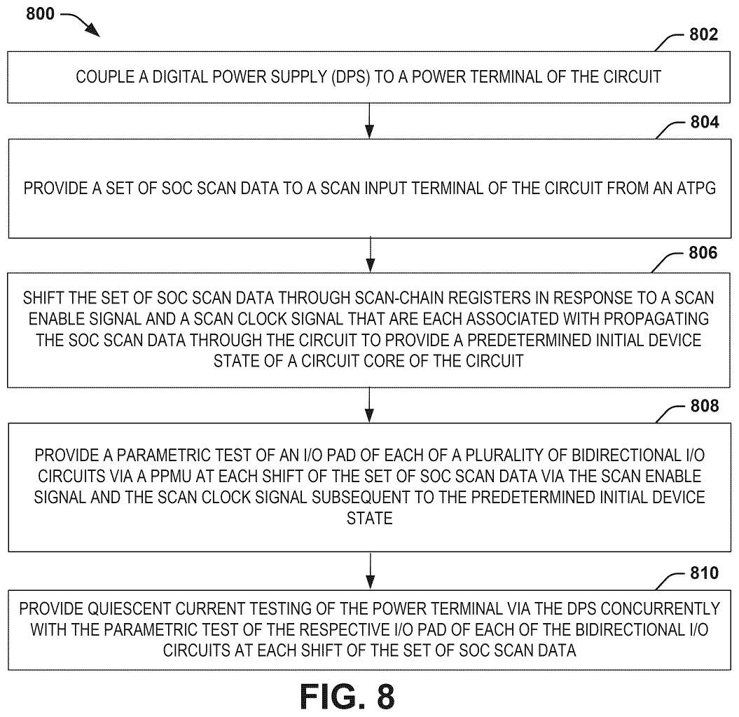

In view of the foregoing structural and functional features described above, methodologies in various aspects of the description will be better appreciated with reference to FIGS. 7 and 8. The methods of FIGS. 7 and 8 are not limited by the illustrated order, as some aspects could, in the present description, occur in different orders and/or concurrently with other aspects from that shown and described herein. Moreover, not all illustrated features may be required to implement methodologies in an aspect of the present examples.

FIG. 7 is an example of a method 700 for testing a circuit (e.g., the DUT 104). At 702, a set of SoC scan data (e.g., the set of SoC scan data SCN) is provided to a scan input terminal (e.g., the TDI scan input terminal 214) of the circuit generated from an ATPG (e.g., the ATPG 108) tool. At 704, the set of SoC scan data is shifted through scan-chain registers (e.g., the scan chain registers 218) in response to a scan enable signal (e.g., the scan enable signal SE) and a scan clock signal (e.g., the scan clock signal SCK) that are each associated with propagating the SoC scan data through the circuit to provide a predetermined initial device state of a circuit core (e.g., the circuit core 202) of the circuit. At 706, a bidirectional I/O control (e.g., the bidirectional I/O control 222) of each of a plurality of bidirectional I/O circuits (e.g., the bidirectional I/O circuits 206) is alternately switched between an input mode and an output mode at each shift of the set of SoC scan data via the scan enable signal and the scan clock signal subsequent to the predetermined initial device state. At 708, input parametric testing of an I/O pad (e.g., the I/O pad 220) of each of the respective bidirectional I/O circuits is provided in the input mode via a PPMU (e.g., the PPMU 106). At 710, output parametric testing of the I/O pad of each of the respective bidirectional I/O circuits is provided in the output mode via the PPMU.

FIG. 8 is another example of a method 800 for testing a circuit (e.g., the DUT 104). At 802, a digital power supply (e.g., the DPS 112) is coupled to a power terminal (e.g., the power terminal 208) of the circuit. At 804, a set of SoC scan data (e.g., the set of SoC scan data SCN) is provided to a scan input terminal (e.g., the TDI scan input terminal 214) of the circuit generated from an ATPG (e.g., the ATPG 108) tool. At 806, the set of SoC scan data is shifted through scan-chain registers (e.g., the scan chain registers 218) in response to a scan enable signal (e.g., the scan enable signal SE) and a scan clock signal (e.g., the scan clock signal SCK) that are each associated with propagating the SoC scan data through the circuit to provide a predetermined initial device state of a circuit core (e.g., the circuit core 202) of the circuit. At 808, a parametric test of an I/O pad (e.g., the I/O pad 220) of each of a plurality of bidirectional I/O circuits (e.g., the bidirectional I/O circuits 206) via a PPMU (e.g., the PPMU 106) at each shift of the set of SoC scan data via the scan enable signal and the scan clock signal subsequent to the predetermined initial device state. At 810, quiescent current measurement test of the power terminal is provided via the DPS concurrently with the parametric test of the respective I/O pad of each of the bidirectional I/O circuits at each shift of the set of SoC scan data.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A circuit comprising:
a circuit core configured to perform an operational function;
scan-chain registers configured to propagate a set of system-on-chip (SoC) scan data that is generated from an automatic test pattern generator (ATPG) input to the circuit to set a different device state of the circuit core at each shift of the SoC scan data; and
a plurality of bidirectional input/output (I/O) circuits each comprising a bidirectional I/O control, an I/O pad, and testing logic, the testing logic being configured to alternately facilitate input parametric testing and output parametric testing of the respective I/O pad via the respective bidirectional I/O control at each shift of the set of SoC scan data.

2. The circuit of claim 1, further comprising a power terminal, wherein the testing logic is configured to facilitate a quiescent current measurement test of the power terminal concurrently with each of the input and output parametric testing of the respective I/O pad of each of the bidirectional I/O circuits at each shift of the set of SoC scan data via a digital power supply (DPS).

3. The circuit of claim 1, wherein the testing logic comprises a sense and drive-back network coupled between an input and an output of the bidirectional I/O control of the respective one of the bidirectional I/O circuit, the sense and drive-back network being configured to alternate between providing a output data signal to the input of the respective bidirectional I/O control to provide the output data signal to the I/O pad in the output parametric testing, and receiving an input data signal provided at the I/O pad from the output of the respective bidirectional I/O control to the sense and drive-back network in the input parametric testing.

4. The circuit of claim 3, wherein the sense and drive-back network comprises a plurality of latching devices arranged in a sequence, each of the latching devices receiving a scan enable signal and a scan clock signal, wherein a last one of the sequence of the latching devices is configured to provide the output data signal to the input of the respective bidirectional I/O control, and wherein a first one of the sequence of the latching devices is configured to receive an inverted version of the input data signal from the output of the respective bidirectional I/O control.

5. The circuit of claim 1, further comprising a bidirectional switching control network configured to alternately set the bidirectional I/O control of each of the bidirectional I/O circuits to an input mode and an output mode at each shift phase or shift and capture phase of the set of SoC scan data in response to a scan enable signal and a scan clock signal that are each associated with propagating the SoC scan data.

6. The circuit of claim 5, wherein the testing logic comprises a pull-up/pull-down control network configured to facilitate a pull-up or pull-down test on the respective I/O pad at a first shift of the set of SoC scan data in the input mode, and to facilitate a pull-down or pull-up test on the respective I/O pad at a second shift of the set of SoC scan data in the input mode.

7. The circuit of claim 5, wherein the bidirectional switching control network comprises a plurality of latching devices arranged in a sequence, each of the latching devices receiving the scan enable signal and the scan clock signal, wherein a last one of the sequence of the latching devices is configured to provide a mode switching signal to the bidirectional I/O control of each of the bidirectional I/O circuits and to each other one of the latching devices in a feedback manner to alternately set each of the bidirectional I/O control of each of the bidirectional I/O circuits to the input mode and the output mode at each shift of the set of SoC scan data in response to the scan clock signal.

8. The circuit of claim 7, wherein the scan enable signal is de-asserted at every other cycle of the scan clock signal to capture a state of the mode switching signal at a first one of the latching devices at a corresponding first cycle of the scan clock signal, and wherein the scan enable signal is asserted at every alternate cycle of the scan clock signal to shift alternate states of the mode switching signal through each of the latching devices at a corresponding second cycle of the scan clock signal.

9. The circuit of claim 5, wherein the testing logic is configured to facilitate the input parametric testing of the respective I/O pad in response to the bidirectional switching control network setting the bidirectional I/O control of each of the bidirectional I/O circuits to the input mode at every other shift of the set of SoC scan data, and to facilitate the output parametric testing of the respective I/O pad in response to the bidirectional switching control network setting the bidirectional I/O control of each of the bidirectional I/O circuits to the output mode at every alternate shift of the set of SoC scan data.

10. The circuit of claim 9, wherein the testing logic is configured to alternate between one of voltage input low or high testing from the respective I/O pad to the circuit core, voltage output high or low testing from the circuit core to the respective I/O pad, voltage input high or low testing from the respective I/O pad to the circuit core, and voltage output low or high testing from the circuit core to the respective I/O pad at each shift of the set of SoC scan data.

11. The circuit of claim 1, further comprising a plurality of multiplexers configured to switch each input of the bidirectional I/O control of each of the bidirectional I/O circuits from the circuit core to the testing logic in response to a test enable signal.

12. A method for testing a circuit, the method comprising:
providing a set of system-on-chip (SoC) scan data to a scan input terminal of the circuit generated from an automatic test pattern generator (ATPG);
shifting the set of SoC scan data through scan-chain registers in response to a scan enable signal and a scan clock signal that are each associated with propagating the SoC scan data through the circuit to provide a predetermined initial device state of a circuit core of the circuit;
alternately switching a bidirectional input/output (I/O) control of each of a plurality of bidirectional I/O circuits between an input mode and an output mode at each shift of the set of SoC scan data via the scan enable signal and the scan clock signal subsequent to the predetermined initial device state;
providing input parametric testing of an I/O pad of each of the respective bidirectional I/O circuits in the input mode via a pin parametric measurement unit (PPMU); and
providing output parametric testing of the I/O pad of each of the respective bidirectional I/O circuits in the output mode via the PPMU.

13. The method of claim 12, further comprising providing a quiescent current measurement test of a power terminal of the circuit via a digital power supply (DPS) concurrently with each of the input and output parametric testing of the respective I/O pad of each of the bidirectional I/O circuits at each shift of the set of SoC scan data.

14. The method of claim 12, wherein each of the bidirectional I/O circuits further comprises testing logic, wherein providing the input parametric testing comprises receiving an input data signal provided at the I/O pad from an output of the respective bidirectional I/O control to the testing logic during the input parametric testing at a first shift of the set of SoC scan data, wherein providing the output parametric testing comprises providing an output data signal from the testing logic to an input of the respective bidirectional I/O control to provide the output data signal to the I/O pad during the output parametric testing at a second shift of the set of SoC scan data subsequent to the first shift.

15. The method of claim 14, further comprising providing a test enable signal to a plurality of multiplexers to switch each input of the respective bidirectional I/O control of each of the bidirectional I/O circuits from the circuit core to the testing logic.

16. The method of claim 12, wherein providing the input and output parametric testing comprises, at each shift of the set of SoC scan data, alternating between:
providing a voltage input low test from the respective I/O pad of each of the respective bidirectional I/O circuits to the circuit core in the input mode via the PPMU;
providing a voltage output high test from the circuit core to the respective I/O pad of each of the respective bidirectional I/O circuits in the output mode via the PPMU;
providing a voltage input high test from the respective I/O pad of each of the respective bidirectional I/O circuits to the circuit core in the input mode via the PPMU; and
providing a voltage output low test from the circuit core to the respective I/O pad of each of the respective bidirectional I/O circuits in the output mode via the PPMU.

17. The method of claim 12, further comprising:
providing a pull-up test on the respective I/O pad of each of the bidirectional I/O controls via the PPMU at a first shift of the set of SoC scan data in the input mode; and
providing a pull-down test on the respective I/O pad of each of the bidirectional I/O controls via the PPMU at a second shift of the set of SoC scan data in the input mode.

18. A circuit comprising:
a power terminal configured to receive input power to the circuit;
a circuit core configured to perform an operational function;
scan-chain registers configured to propagate a set of system-on-chip (SoC) scan data that is input to the circuit from an automatic test pattern generator (ATPG) to set a different device state of the circuit core at each shift of the SoC scan data; and
a plurality of bidirectional input/output (I/O) circuits each comprising a bidirectional I/O control, an I/O pad, and testing logic, the testing logic being configured to facilitate input and output parametric testing of the I/O pad via the respective bidirectional I/O control by a pin parametric measurement unit (PPMU) concurrently with a quiescent current measurement test of the power terminal by a digital power supply (DPS) at each shift of the set of SoC scan data.

19. The circuit of claim 18, wherein the testing logic comprises a sense and drive-back network coupled between an input and an output of the bidirectional I/O control of the respective one of the bidirectional I/O circuit, the sense and drive-back network being configured to alternate between providing a output data signal to the input of the respective bidirectional I/O control to provide the output data signal to the I/O pad in the output parametric testing, and receiving an input data signal provided at the I/O pad from the output of the respective bidirectional I/O control to the sense and drive-back network in the input parametric testing.

20. The circuit of claim 18, further comprising a bidirectional switching control network configured to alternately set the respective bidirectional I/O control of each of the bidirectional I/O circuits to an input mode and an output mode at each shift of the set of SoC scan data in response to a scan enable signal and a scan clock signal that are each associated with propagating the SoC scan data.

21. The circuit of claim 20, wherein the testing logic comprises a pull-up/pull-down control network configured to facilitate a pull-up test on the respective I/O pad via the PPMU at a first shift of the set of SoC scan data in the input mode, and to facilitate a pull-down test on the respective I/O pad via the PPMU at a second shift of the set of SoC scan data in the input mode.

22. A method for testing a circuit, the method comprising:
coupling a digital power supply (DPS) to a power terminal of the circuit;
providing a set of system-on-chip (SoC) scan data to a scan input terminal of the circuit from an automatic test pattern generator (ATPG);
shifting the set of SoC scan data through scan-chain registers in response to a scan enable signal and a scan clock signal that are each associated with propagating the SoC scan data through the circuit to provide a predetermined initial device state of a circuit core of the circuit;
providing a parametric test of an input/output (I/O) pad of each of a plurality of bidirectional I/O circuits via a pin parametric measurement unit (PPMU) at each shift of the set of SoC scan data via the scan enable signal and the scan clock signal subsequent to the predetermined initial device state; and
providing a quiescent current measurement test of the power terminal via the DPS concurrently with the parametric test of the respective I/O pad of each of the bidirectional I/O circuits at each shift of the set of SoC scan data.

23. The method of claim 22, wherein providing the parametric test further comprises:
alternately switching a bidirectional I/O control of each of the bidirectional I/O circuits between an input mode and an output mode at each shift of the set of SoC scan data;
providing input parametric testing of the I/O pad of each of the respective bidirectional I/O circuits in the input mode via the PPMU; and
providing output parametric testing of the I/O pad of each of the respective bidirectional I/O circuits in the output mode via the PPMU.

24. The method of claim 23, wherein each of the bidirectional I/O circuits comprises testing logic, wherein providing the input parametric testing comprises receiving an input data signal provided at the I/O pad from the output of the respective bidirectional I/O control to the testing logic during the input parametric testing at a first shift of the set of SoC scan data, wherein providing the output parametric testing comprises providing an output data signal from the testing logic to the input of the respective bidirectional I/O control to provide the output data signal to the I/O pad during the output parametric testing at a second shift of the set of SoC scan data subsequent to the first shift.

25. The method of claim 23, wherein providing the input and output parametric testing comprises, at each shift of the set of SoC scan data, alternating between:
providing a voltage input low test from the respective I/O pad of each of the respective bidirectional I/O circuits to the circuit core in the input mode via the PPMU;
providing a voltage output high test from the circuit core to the respective I/O pad of each of the respective bidirectional I/O circuits in the output mode via the PPMU;
providing a voltage input high test from the respective I/O pad of each of the respective bidirectional I/O circuits to the circuit core in the input mode via the PPMU; and
providing a voltage output low test from the circuit core to the respective I/O pad of each of the respective bidirectional I/O circuits in the output mode via the PPMU.

26. The method of claim 23, further comprising:
providing a pull-up test on the respective I/O pad of each of the bidirectional I/O circuits via the PPMU at a first shift of the set of SoC scan data in the input mode; and
providing a pull-down test on the respective I/O pad of each of the bidirectional I/O circuits via the PPMU at a second shift of the set of SoC scan data in the input mode.

27. A circuit comprising:
a bidirectional control switching network having a first input, a second input, a third input, and a plurality of outputs, the first input of the bidirectional control switching network being adapted to receive a set of SoC scan data, the second input of the bidirectional control switching network being adapted to receive a scan enable signal, and the third input of the bidirectional control switching network being adapted to receive a scan clock signal; and
a plurality of bidirectional I/O circuits, each of the bidirectional input/output (I/O) circuits comprising:
a sense and drive-back network having a first input, a second input, a third input, a fourth input, and an output, the first input of the sense and drive-back network being adapted to receive the set of SoC scan data, the second input of the sense and drive-back network being adapted to receive the scan enable signal, and the third input of the sense and drive-back network being adapted to receive the scan clock signal; and
a bidirectional I/O control having a first input, a second input, an output, and an I/O pad, the first input of the bidirectional I/O control being coupled to one of the plurality of outputs of the bidirectional control switching network, the second input of the bidirectional I/O control being coupled to the output of the sense and drive-back network, and the output of the bidirectional I/O control being coupled the fourth input of the sense and drive-back network.

28. The circuit of claim 27, wherein the bidirectional control switching network comprises:
a first latching device having a first input, a second input, a third input, a fourth input, and an output, the first input corresponding to the first input of the bidirectional control switching network, the second input corresponding to the second input of the bidirectional control switching network, the third input corresponding to the third input of the bidirectional control switching network;
a second latching device having a first input, a second input, a third input, a fourth input, and an output, the first input being coupled to the output of the first latching device, the second input corresponding to the second input of the bidirectional control switching network, the third input corresponding to the third input of the bidirectional control switching network;
a third latching device having a first input, a second input, a third input, a fourth input, and an output, the first input being coupled to the output of the second latching device, the second input corresponding to the second input of the bidirectional control switching network, the third input corresponding to the third input of the bidirectional control switching network, the output corresponding to one of the plurality of outputs of the bidirectional control switching network and being coupled to the fourth input of the first latching device and the fourth input of the third latching device; and
an inverter having an input and an output, the input being coupled to the output of the third latching device and the output being coupled to the fourth input of the second latching device.

29. The circuit of claim 27, wherein the sense and drive-back network of each of the bidirectional I/O circuits comprises:
a first latching device having a first input, a second input, a third input, a fourth input, and an output, the first input corresponding to the first input of the sense and drive-back network, the second input corresponding to the second input of the sense and drive-back network, the third input corresponding to the third input of the sense and drive-back network;
a second latching device having a first input, a second input, a third input, a fourth input, and an output, the first input being coupled to the output of the first latching device, the second input corresponding to the second input of the bidirectional control switching network, the third input corresponding to the third input of the bidirectional control switching network, and the output being coupled to the fourth input of the second latching device; and
an inverter having an input and an output, the input corresponding to the fourth input of the sense and drive-back network and the output being coupled to the fourth input of the first latching device.

30. The circuit of claim 27, wherein each of the bidirectional I/O circuits further comprises:
a first multiplexer having a first input, a second input, a third input, and an output, the first input being coupled to a first output of a circuit core, the second input being coupled to one of the outputs of the bidirectional switching control network, the third input being adapted to receive a mode control signal, and the output being coupled to the first input of the respective bidirectional I/O control;
a second multiplexer having a first input, a second input, a third input, and an output, the first input being coupled to a second output of the circuit core, the second input being coupled to the output of the respective sense and drive-back network, the third input being adapted to receive the mode control signal, and the output being coupled to the second input of the respective bidirectional I/O control;
a third multiplexer having a first input, a second input, a third input, and an output, the first input being coupled to a third output of the circuit core, the second input being coupled to a first output of a pull-up/pull-down network, the third input being adapted to receive the mode control signal, and the output being coupled to a third input of the respective bidirectional I/O control; and
a fourth multiplexer having a first input, a second input, a third input, and an output, the first input being coupled to a fourth output of the circuit core, the second input being coupled to a second output of a pull-up/pull-down network, the third input being adapted to receive the mode control signal, and the output being coupled to a fourth input of the respective bidirectional I/O control.
